(19) United States
(12) Patent Application Publication
(10) Pub. No.: US 2004/0227202 A1
(43) Pub. Date: Nov. 18, 2004

(54) Isotopically enriched piezoelectric devices and method for making the same

(76) Inventor: Philip V. Pesavento, Fairmont, WV (US)

Correspondence Address: REED SMITH, LLP, ATTN: PATENT RECORDS DEPARTMENT, 599 LEXINGTON AVENUE, 29TH FLOOR, NEW YORK, NY, 10022-7650, US

(21) Appl. No.: 10/719,943

(22) Filed: Nov. 21, 2003

Related U.S. Application Data
(60) Provisional application No. 60/430,171, filed on Dec. 2, 2002.

(51) Int. Cl. H01L 21/00; H01L 29/82

(52) U.S. Cl. 257/416; 438/50

(57) ABSTRACT

Piezoelectric devices made from lightest isotope enriched materials with significantly improved thermal conductivity, frequency stability and phase noise qualities. The isotopically enriched materials may consist of a single crystal and may include silicon dioxide, zinc oxide, titanium dioxide, lithium niobate, lithium tantalate, langasite, langatate, and lead-zirconate-titanate. Piezoelectric devices of greatly improved frequency, and phase and power stability/power handling characteristics are realized for use in RF communications, acoustic wave crystal filters, portable clocks, oscillators, resonators, speakers, ultrasonic speakers, ultrasonic transducers, material inspection, medical diagnostic imaging and non-invasive surgical equipment, and acousto-optic modulators. A method for producing a single crystal of an isotopically enriched material includes the steps of obtaining the isotopically enriched material in powder form, converting the isotopically enriched material powder into dendrite crystals via a first hydrothermal process, and producing a single crystal from the dendrite crystals via a second hydrothermal process.

### CROSS REFERENCE TO RELATED APPLICATIONS

This application claims priority to U.S. provisional application, serial No. 60/430,171 filed on Dec. 2, 2002 which is hereby incorporated by reference.

### BACKGROUND OF THE INVENTION

1. Field of the Invention

The present invention relates generally to piezoelectric devices and, more particularly, to piezoelectric devices made from isotopically enriched piezoelectric materials, and methods for making the same, having improved thermal conductivity, frequency stability and phase noise qualities over currently used piezoelectric materials of natural isotopic composition.

2. Description of the Related Art

In 1880, brothers Pierre and Jacques Curie discovered and developed the phenomenon of piezoelectricity. Piezoelectricity is the physical property where certain materials, among them crystal quartz, can be made to mechanically change their shape by applying an electric field thereto and the reciprocal phenomenon that by mechanically flexing or vibrating the crystal, the crystal generates an electric field. Over time others discovered that distinct and stable frequencies under electrical excitation can be generated by varying the crystal directions and orientations to the crystal axis, as well as the mechanical dimensions of the crystal.

During World War II, Pahl, Nacken, Spangenberg, Joos, Gunther, and Chytrek in Germany developed a process for growing synthetic quartz crystals using a hydrothermal growth technique. In the 1950s, Bell Laboratories implemented this technique on an industrial scale. Since that time, essentially all commercially utilized quartz crystals have been grown synthetically by this hydrothermal method. Other piezoelectric materials are grown synthetically using similar methods.

It is well known that the use of synthetic quartz crystals of natural isotopic composition as resonators in electronic clock (square-wave) and electronic oscillator (sine-wave) circuits is limited by the crystal's inherently low short and long term frequency stability, low power handling capability, and high phase noise. Similar limitations affect the application of other piezoelectric materials. Typically, these limitations are attributed to the low thermal conductivity of the piezoelectric materials and phonon scattering naturally occurring therein. The phonon scattering, which occurs in crystal quartz of natural isotopic composition, for example, further reduces the thermal conductivity thereof as well as the Quality Factor (Q)—an important parameter affecting the frequency and phase stability of clocks and oscillators. Due to these limitations, external temperature stabilization circuitry is required to accompany the quartz and, in most instances, has limited the use of quartz crystals to only very low power applications.

Typically, synthetic quartz is a compound made up of two elements, silicon and oxygen. Naturally occurring silicon is composed of three isotopes, Si28, Si29, and Si30, in the following proportions: 92.4% Si28, 4.6% Si29, and 3% S130. Naturally occurring oxygen is composed of three isotopes as well, O16, O17, and O18, with natural abundances of in the following proportions: 99.76%, 0.04% and 0.2%, respectively.

Frederick Soddy first discovered and coined the term “isotopes” shortly before World War I. Since its discovery, substantial research has occurred to develop means for isolating isotopically enriched materials. During the 1920s and 1930s, developers used mass spectrometers to separate small quantities of isotopically enriched materials from materials having isotopic levels occurring naturally. Bulk separation of isotopically enriched materials was first performed on Uranium 235 (U235) for the Manhattan Project during World War II. The bulk separation techniques used for Little Boy (first atomic bomb) included electromagnetic separation technique (calutrons) assisted by the liquid thermal diffusion technique (also known as the Clusius-Dickel method which was modified by Philip Abelson).

The cost of these early techniques for stable (non-radioactive) isotope enriched materials was not subsidized by the United States government, so the customers for stable isotopes were charged full price, several million dollars per gram being standard. As a result of this high cost of separation, isotopically enriched materials had limited application.

It was not until the fall of the Berlin Wall in 1991 and the collapse of the USSR that the United States had access to stable isotopes at reasonable prices upon the development of separation methods combining gas centrifuge and laser isotope separation techniques. The buildup of commercial isotope separation facilities both in the United States and Europe in preparation for an assumed large increase in nuclear power plant construction (which never materialized) resulted in a large amount of excess isotope separation capacity which was not being used. The United States government was for many years the main supplier of all isotopically enriched materials out of the Oak Ridge National Laboratory facility, which for stable or radioactive isotopes other than U238 enriched in U235, would cost approximately $1,000 per milligram. The unused capacity of the commercial facilities has made it possible to get isotopically enriched material for as little as $50 per gram.

However, it took almost a decade for the condensed matter physics community to take advantage of this now readily accessible material, so only sporadic experimentation has been done to characterize isotopic effects in single crystals of enriched elements. Further, the United States and European high-tech industries seem to be wholly unaware of this change in the price structure, so little commercialization of stable isotopically enriched materials in this field has resulted to date.

The three isotopically enriched materials that have received the bulk of the experimental work are diamond (single crystal cubic carbon), single crystal germanium and single crystal silicon. Limited testing of bulk samples of isotopically enriched materials has demonstrated great improvements in the physical properties of these elemental single crystals. Recently, the new superconductor MgB₂ has shown marked improvements in its transition temperature when made from isotopically enriched constituents.

Isonics Corporation has done extensive characterization of isotopically enriched materials, both stable and radioactive, including silicon, which exhibited substantial improvements in thermal conductivity, carrier mobility and drift velocities for semiconductor applications compared to natural isotopic composition silicon single crystals. Similar improvements have been seen in isotopically enriched diamond and germanium.

The most dramatic improvements in material properties have been in the measurements of thermal conductivity. According to the accepted Debye theory of heat transfer, lattice vibrations (carried by high frequency phonons) cause the transfer of thermal energy through a crystalline solid. These lattice vibrations are of very high frequencies, comparable to the electromagnetic frequencies of radiant heat. The use of isotopically enriched materials were found to increase the thermal conductivity of a material by anywhere from a factor of 1.5 near room temperature in some materials to a factor of 20 at cryogenic temperatures. This increase has been attributed to a reduction in phonon scattering caused by the isotopically enriched elements. The quantum mechanics of macroscopic systems has been applied most frequently to semiconductors, but has only been applied to piezoelectric devices as regards thermoconductivity but not to explain piezoelectric effect, until this invention.

In light of the limitations of current synthetic piezoelectric materials, including quartz crystals, as discussed above, limitations which have existed for decades and were presumed to be inherent in the use of these materials in piezoelectric applications, it would be desirable to develop quartz crystals and other piezoelectric materials having substantially increased short and long term frequency stability, increased power handling capability, and decreased phase noise. Accordingly, the present invention uses the teachings from the recently unrelated fields of quantum mechanics and piezoelectrics in limiting the phonon scattering and increasing thermal conductivity through the use of isotopically enriched materials in the manufacture of synthetic piezoelectric materials and devices using the same.

The present invention in its various preferred embodiments described herein provides numerous improvements and benefits over the prior art piezoelectric devices and methods.

### SUMMARY OF THE INVENTION

Accordingly, in at least one preferred embodiment, the present invention provides a device comprising an isotopically enriched piezoelectric material which may include isotopically enriched silicon dioxide, zinc oxide, titanium dioxide, lithium niobate, lithium tantalate, langasite, langatate, or lead-zirconate-titanate (PZT). Preferably, the lightest isotope of the material is the one enriched to provide the most improvement in piezoelectric properties including improved thermal conductivity, frequency stability and phase noise qualities. The isotopically enriched material for use in the present invention may also consist of a single crystal.

In an additional preferred embodiment, the present invention provides a method for producing single crystals of an isotopically enriched piezoelectric material comprising the steps of obtaining the isotopically enriched material in powder form, converting the isotopically enriched piezoelectric material powder into dendrite crystals by means of a first hydrothermal process; and producing a single crystal from the dendrite crystals by means of a second hydrothermal process.

By using isotopically enriched piezoelectric materials, devices of greatly improved performance can be realized. New applications for such isotopically enriched piezoelectric materials of the present invention include: closer spacing of communications channels in radio-frequency equipment; lower insertion loss and higher power handling capability of discrete and surface acoustic wave crystal filters; improved frequency and phase stability in less demanding applications without the need for temperature stabilization; replacement of portable atomic clocks with quartz resonators of equal performance at a fraction of the size and cost; the ability to build compact, high powered, ultrasonic transducers in the MHz range for watercraft wake elimination, material inspection, medical diagnostic imaging, non-invasive surgical procedures and non-linear response ultrasonic beam speaker systems; high powered acousto-optic modulators, and other applications where the isotopically enriched material will result in improved frequency, phase stability and power stability/power handling characteristics.

Other and further features and advantages of the invention will appear more fully from the following detailed description.

### BRIEF DESCRIPTION OF THE DRAWINGS

For the present invention to be clearly understood and readily practiced, the present invention will be described in conjunction with the following figures, wherein like reference characters designate the same or similar elements, which figures are incorporated into and constitute a part of the specification, wherein:

FIG. 1 is a graph of the Value of Q versus frequency which shows the improved Q Value of the isotopically enriched piezoelectric materials and devices of the present invention;

FIG. 2 is a graph of frequency stability versus time which shows the improved frequency stability of the isotopically enriched piezoelectric materials and devices of the present invention;

FIG. 3 is a graph of carrier phase noise versus offset from the carrier which shows the reduced phase noise produced by the isotopically enriched piezoelectric materials and devices of the present invention;

FIG. 4 is a circuit diagram for clock and oscillator circuits in series and parallel which utilize isotopically enriched piezoelectric materials in accordance with the present invention;

FIG. 5 is a schematic view of a mounted crystal quartz resonator utilizing an isotopically enriched piezoelectric material in accordance with the present invention;

FIG. 6 is a partial schematic drawing of a transverse type surface acoustic wave filter comprising an isotopically enriched piezoelectric material in accordance with the present invention;

FIG. 7 is a schematic view of a device having a transducer comprising an isotopically enriched piezoelectric material in accordance with the present invention for performing non-invasive acoustic detection of tumors and acoustic surgery;

FIG. 8 is a circuit diagram for a phase comparison monopulse radar comprising a low phase noise reference oscillator having a resonator made from an isotopically enriched piezoelectric material in accordance with the present invention;

FIG. 9 is a cross-sectional view of a transducer for an ultrasonic cleaning application made from an isotopically enriched piezoelectric material in accordance with the present invention; and

FIG. 10 is a schematic view of a resonator employing an isotopically enriched piezoelectric material in accordance with the present invention for use as a speaker or buzzer.

### DETAILED DESCRIPTION OF THE INVENTION

It is to be understood that the figures and descriptions of the present invention have been simplified to illustrate elements that are relevant for a clear understanding of the present invention, while eliminating, for purposes of clarity, other elements that may be well known. Those of ordinary skill in the art will recognize that other elements are desirable and/or required in order to implement the present invention. However, because such elements are well known in the art, and because they do not facilitate a better understanding of the present invention, a discussion of such elements is not provided herein. The detailed description of the present invention and the preferred embodiment(s) thereof are set forth in detail below with reference to the attached drawings.

A preferred application of the present invention relates to the use of isotopically enriched silicon in silicon compounds, specifically single crystal silicon dioxide (often referred to as single crystal quartz, or just quartz). Using isotopically enriched elements rather than the naturally occurring isotopic composition in silicon dioxide (three silicon isotopes and, three oxygen isotopes), reduces phonon scattering resulting in improved thermal conductivity, and more importantly improved frequency stability and reduced phase noise in piezoelectric applications, including without limitation quartz clocks and oscillator circuits. With improved thermal conductivity, accompanying external temperature stabilization circuitry is no longer required and, in most instances, the quartz can now be applied to higher power applications, to which it was not suitable heretofore.

Preferably, isotopically enriched silicon, specifically 14 silicon 28 (₁₄Si²⁸, usually abbreviated Si28) is used in the production of the synthetic crystal of the present invention. This isotopically enriched element greatly reduces phonon scattering (caused by dislocation from different sized atoms in the crystal's lattice) within the crystal at and below room temperature compared to naturally occurring silicon, which is composed of the three isotopes ₁₄Si²⁸, ₁₄Si²⁹ and ₁₄Si³³ (usually abbreviated Si28, Si29, and Si30). The greatest improvement in material properties occurs when the isotope that is enriched is the lightest one, in this case Si28. The reduced phonon scattering translates directly into improved thermal conductivity, anywhere from a factor of three near room temperature to a factor of seven at reduced temperatures, and further results in reduced damping in the crystal, raising the quartz crystal's Q from 20 million to 40 million at 1 MHz, and therefore increases its frequency stability by roughly a factor of 10. Additionally, the reduced phonon scattering results in a much sharper optical spectra compared to the multi-isotopic material generally available, as well as improving phase stability by −20 dBc/Hz at 100 Hz offset from the carrier and −10 dBc at 1 through 10 kHz offset from the carrier. Finally, the increased thermal conductivity decreases warm-up time, and improves power-handling capability in power transducer applications like acoustic surgery, filters and ship wake reduction.

Preferably, the silicon isotope is enriched to at least 99% of the silicon component of the silicon dioxide of this application. It is important to note that the level of enrichment of any isotope will increase exponentially the expense of the enriched material; therefore, the level of enrichment should be commensurate with the level of improvement desired in the piezoelectric device.

Preferably, this preferred application of the present invention also comprises the use of isotopically enriched 8oxygen16 (₈O¹⁶ often abbreviated O16), to form isotopically enriched silicon dioxide. Again, this is the lightest of the isotopes in naturally occurring oxygen, and therefore should produce the best results. Furthermore, it is important to note that although preferred, it is not crucial to use isotopically enriched oxygen to achieve generally desirable results in light of the fact that 99.76% of naturally occurring oxygen comprises the isotope 016 and therefore enrichment thereof while beneficial would have less dramatic of an effect than the enrichment of the silicon.

In this application, the isotopically enriched silicon dioxide, created from isotopically enriched silicon and natural or isotopically enriched oxygen, is then used for the hydrothermal growth of isotopically enriched, synthetic, single crystal quartz.

The preferred method of manufacturing isotopically enriched cultured quartz crystals does not vary from the manufacture of traditional synthetic quartz crystals. The isotopically enriched silicon dioxide is merely substituted for the silicon dioxide at natural levels in the manufacture of the crystals. Preferably in the form of a very fine quartz powder, the isotopically enriched silicon dioxide is first converted into a large number of small dendrite crystals, then into a much larger single crystal both by means of the hydrothermal growth technique first developed by the Bell Laboratories. The crystal's main axes are then determined by x-ray diffraction (crystallography), and the crystal is sliced, ground, polished and etched using traditional techniques into what are known in the industry as SC cut slabs. The crystal is finally mounted in a vacuum-sealed low loss mounting that is industry standard for SC cut crystals.

The use of isotopically enriched materials provides for piezoelectric devices of greatly improved performance. New applications for such isotopically enriched piezoelectric materials of the present invention include: closer spacing of communications channels in radio-frequency equipment; lower insertion loss and higher power handling capability of discrete and surface acoustic wave crystal filters; improved frequency and phase stability in less demanding applications without the need for temperature stabilization; replacement of portable atomic clocks with quartz resonators of equal performance; the ability to build compact, high powered, ultrasonic transducers in the MHz range for watercraft wake elimination, material inspection, medical diagnostic imaging and non-invasive surgical procedures; high powered acousto-optic modulators, and other applications where the isotopically enriched material will result in improved frequency, and phase and power stability/power handling characteristics.

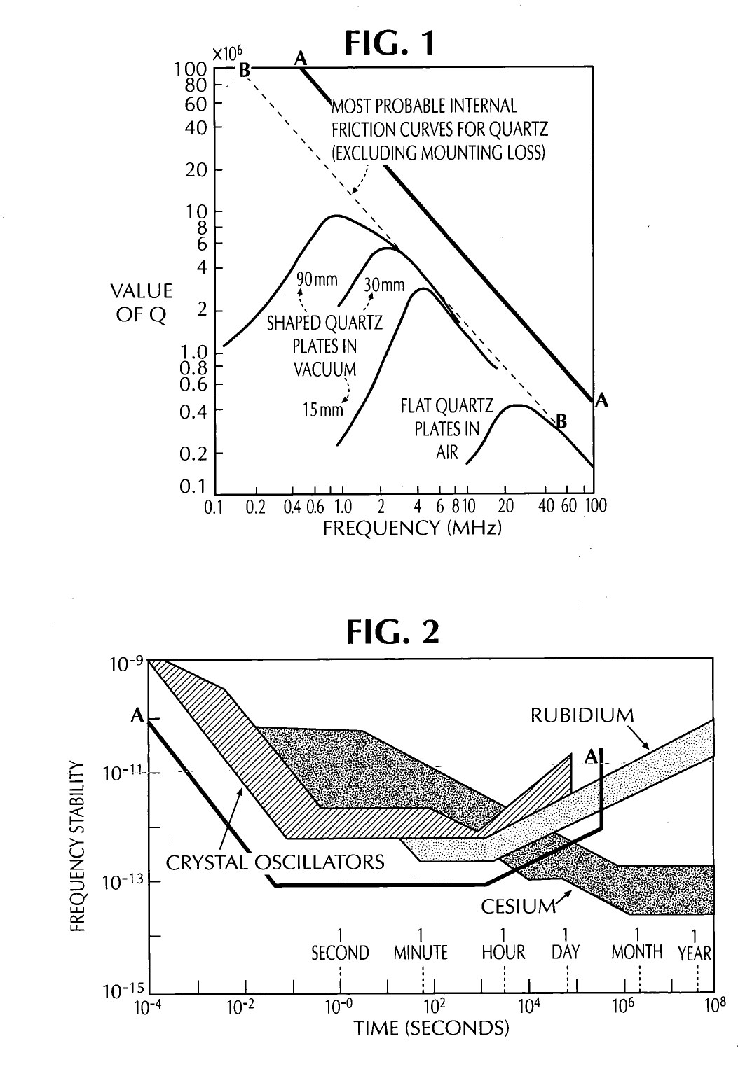

FIG. 1 is a graph of the value of Q versus frequency which shows the improved Q value of the isotopically enriched piezoelectric materials and devices of the present invention. Specifically, FIG. 1 illustrates the accepted theoretical and practical performance of natural and synthetic quartz resonators made from quartz of natural isotopic composition with respect to electromechanical Q. The solid Line A-A on FIG. 1 represents the theoretical limit of Q when resonators are made from isotopically enriched quartz comprising at least 99.9% Si28 and 99.9% 016. The dashed Line B-B on FIG. 1 represents the theoretical Q versus frequency, while the solid curved lines represent measured values of Q.

FIG. 2 is a graph of frequency stability versus time which shows the improved frequency stability of the isotopically enriched piezoelectric materials and devices of the present invention. In particular, FIG. 2 illustrates short and long term frequency stability of quartz resonators made from quartz of natural isotopic composition in comparison with two types of atomic clocks, cesium and rubidium atomic clocks. The shaded areas represent the performance of quartz, rubidium and cesium, respectively. The solid Line A-A represents the theoretical limits in improvements to both the short and long term frequency stability in electronic clocks comprising resonators made from isotopically enriched quartz of at least 99.9% Si28 and 99.9% 016.

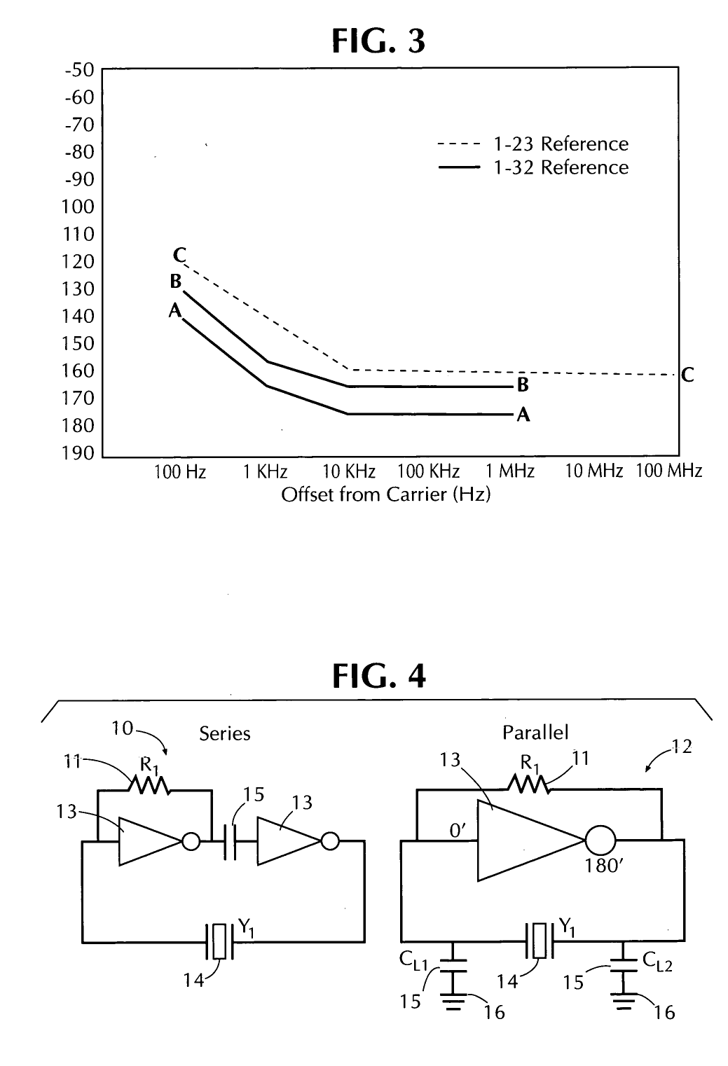

FIG. 3 is a graph of carrier phase noise versus offset from the carrier which shows the reduced phase noise produced by the isotopically enriched piezoelectric materials and devices of the present invention. Specifically, FIG. 3 illustrates a more subtle electrical property of quartz resonators, namely phase stability, also called phase noise. Phase stability differs from frequency stability, in that it is more of a short-term stability parameter (time span of seconds) rather than a long term (minutes to hours to days).

Phase stability is important in two specific electronic applications: radar systems and communications systems. In radar systems, the ability of a radar system to detect moving airborne targets and reject reflections from ground clutter, is highly dependent on the phase stability of the oscillator, which generates the radiated signal in the radar transmitter and the phase reference signal in the radar receiver. In communications systems, particularly when phase modulation is used, the number of phases (anywhere from 2 to 128 phases are presently used for phase shift modulated communications systems) that can be accommodated within a certain U.S. government allocated band of frequency spectrum is dependent on the phase stability of the phase modulator, which is in turn dependent on the phase stability of the oscillator used as the phase reference.

The bottom Curve A-A in FIG. 3 represents the expected improvement by using isotopically enriched quartz resonators containing at least 99.9% Si28 and 99.9% 016. The middle Curve B-B represents the very best performance obtained from quartz resonators of natural isotopic composition. The upper dashed Curve C-C in FIG. 3 represents the minimum acceptable phase noise or phase stability performance in modern radar systems.

FIG. 4 is a circuit diagram for clock and oscillator circuits in series and parallel which utilize isotopically enriched piezoelectric materials in accordance with the present invention. Specifically, FIG. 4 illustrates typical clock and oscillator circuits 10 and 12 which operate in series and parallel, respectively, wherein the substitution of isotopically enriched quartz as the frequency determining element in the quartz crystal resonator (Y₁)14 results in reduced phase and amplitude noise. In addition to the quartz crystal resonator 14, the circuits 10, 12 comprise resistors 11, inverting amplifiers 13, capacitors 15 and ground connections 16. The circuits 10, 12 also typically comprise power lines which have been omitted for clarity. The clock or oscillator signal output (also not shown) would typically emanate from one of the inverted amplifiers 13.

Referring to FIG. 4, the use of isotopically enriched quartz enhances the performance of the quartz clock circuits to equal that of modern portable atomic clocks. Isotopically enriched quartz clocks, however, are advantageous in that they are approximately 1,000 times less expensive and many times smaller than current atomic clocks.

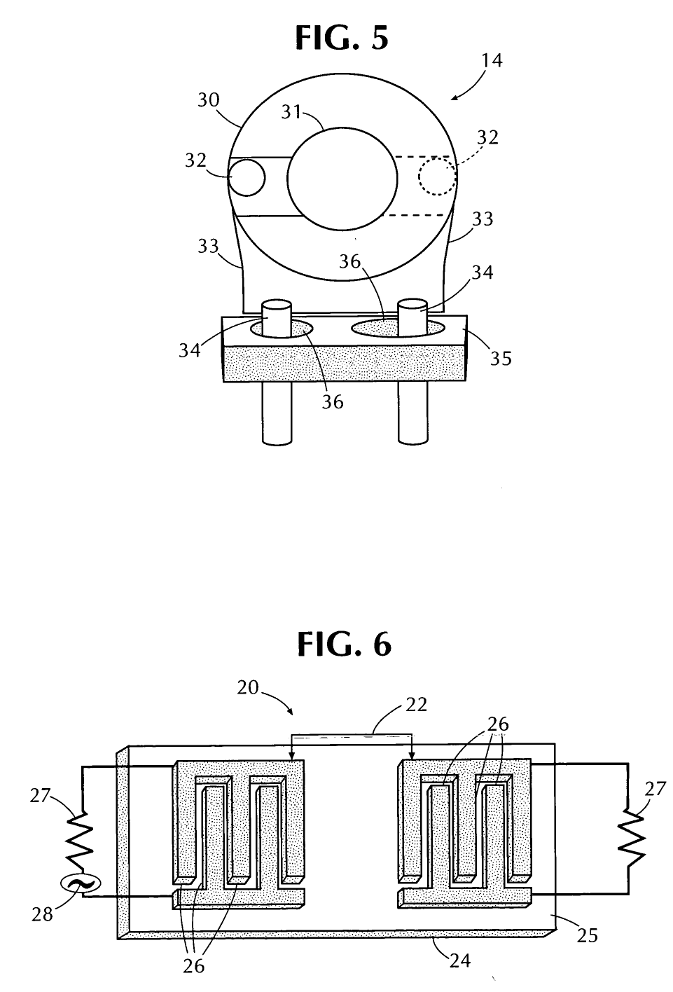

FIG. 5 is a schematic view of a mounted crystal quartz resonator utilizing an isotopically enriched piezoelectric material in accordance with the present invention. The quartz crystal resonator 14 of the present invention, as shown in FIG. 5, comprises a disk 30 made from a single crystal of isotopically enriched quartz containing at least 99.9% Si28 and 99.9% 016. Circular electrodes 31, preferably comprising gold or aluminum, are deposited on both sides of the disk 30. Electrical and mechanical mounting pads 32 are also disposed on both sides of the disk 30. Wires 33 act as mechanical mounts and electrical connectors leading to electrical output pins 34. The pins 34 are mounted in a header 35 with an isolating glass 36 having the same coefficient of thermal expansion as header 35. Preferably, the resonator 14 is hermetically sealed in a metal casing (not shown), in which a vacuum is often formed to improve performance further, as is well known in the art.

FIG. 6 is a partial schematic drawing of a transverse type surface acoustic wave filter comprising an isotopically enriched piezoelectric material in accordance with the present invention. In particular, FIG. 6 shows a transverse type surface acoustic wave filter/resonator 20 comprising a substrate 24 comprising an isotopically enriched piezoelectric material, such as isotopically enriched quartz containing at least 99.9% Si28 and 99.9% 016. The surface acoustic wave filter/resonator includes interdigital transducers 22 etched into the metal film layer 25, usually aluminum, that has been deposited onto the substrate 24. The individual fingers 26 of the interdigital transducers 22 can have equal lengths (as shown) or varying lengths, to vary the filter's electrical characteristics as required.

The transverse type surface acoustic wave filter/resonator 20 of FIG. 6 is a single-phase transducer also comprising resistors 27 and a sine wave generator 28. The use of isotopically enriched piezoelectric materials according to the present invention also applies in the construction of surface acoustic wave filter/resonators 20 employing multi-phase transducers, which have shown improved performance over single-phase types. Improved power handling, pass-band characteristic and lower transmission losses result from the use of isotopically enriched quartz in the transverse type surface acoustic wave filter/resonator according to the present invention. Although not shown, longitudinal type surface acoustic wave filters may also be made in accordance with the present invention.

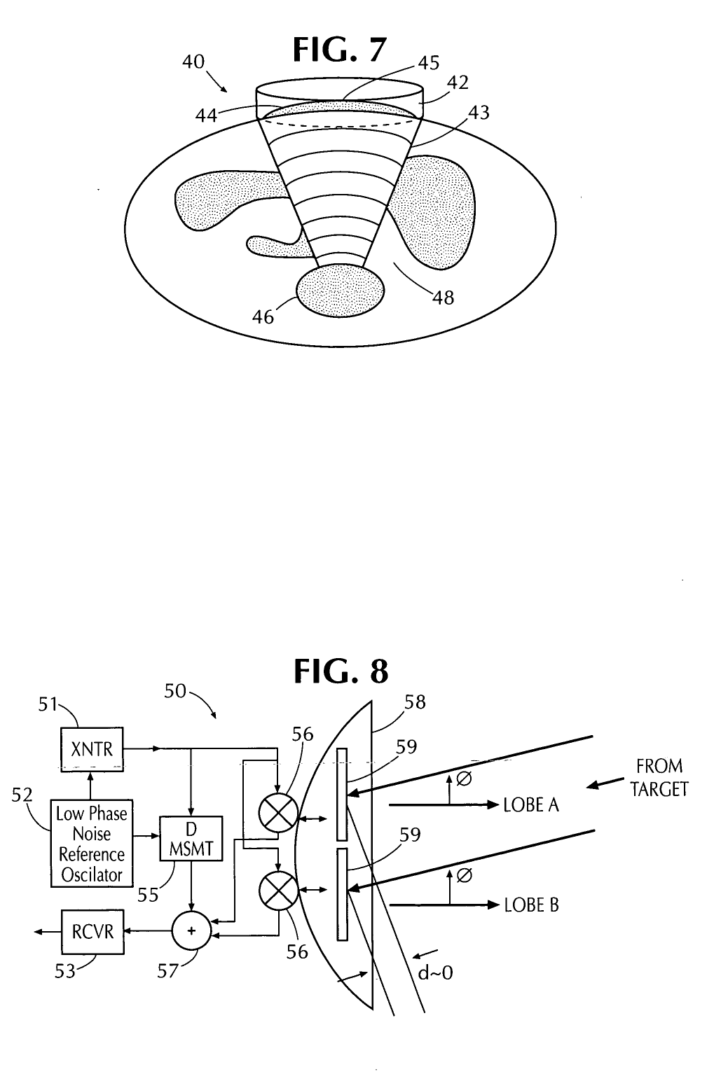

FIG. 7 is a schematic view of a device having a transducer comprising an isotopically enriched piezoelectric material in accordance with the present invention for performing non-invasive acoustic detection of tumors and acoustic surgery. Referring to FIG. 7, a high-powered device 40 for performing non-invasive acoustic detection of tumors and acoustic surgery is shown which includes a transducer 42 defining a concave bowl 44 that is filled with a coupling medium such as water or gel 45. The supporting structure, metal electrodes, power supply lines and power supply have not been shown for purposes of clarity.

When energized, the transducer 42 produces a high-intensity ultrasound beam 43 that is passed through the coupling medium 45. The device 40 is set up so that the acoustic energy comes to a focus at the treatment site, a tumor 46 as illustrated in FIG. 7, or internal bleeding to be stopped by cauterizing local blood vessels (not shown). Because the ultrasound energy is not focused on the intermediate tissue 48, it is not damaged. The use of isotopically enriched quartz to make the transducer 42 allows for higher power levels, higher frequency operation and higher reliability in surgical applications.

Prior piezoelectric acoustic transducers have typically been made from lead-zirconate-titanate, usually referred to as PZT. Quartz of natural isotopic composition has not been used because of its inability to be driven at high power levels without breaking. PZT can be driven at high power levels but it is limited by the maximum frequency that it can be operated at, a few hundred kHz to a few MHz. Using isotopically enriched quartz in accordance with the present invention greatly improves the thermal conductivity of the transducer 42 and allows it to be driven at high enough power levels for this high power application.

In addition, the maximum frequency capability of the isotopically enriched quartz is at least two orders of magnitude higher than that of PZT, which allows higher electrical to acoustic conversion efficiency, higher resolution imaging of the internal organs and more tightly focused beams to perform acoustic surgery, such as that diagrammed in FIG. 7. The more tightly focused ultrasonic beam 43 produced in accordance with the present invention allows less energy to be used to produce the same power density as the prior art devices that were not capable of a tight focus. Thus, the lower power requirement reduces the chances of damaging tissue 48 surrounding the targeted area 46. The single crystal isotopically enriched quartz transducer 42 is also much more resistant to fatigue cracking than the PZT used in prior art devices. As a result, the transducer 42 has a much greater life expectancy than such prior art devices.

FIG. 8 is a circuit diagram for a phase comparison monopulse radar comprising a low phase noise reference oscillator having a resonator made from an isotopically enriched piezoelectric material in accordance with the present invention. Specifically, FIG. 8 shows a circuit for a phase comparison monopulse radar 50 having a low phase noise reference oscillator 52 that utilizes a resonator made from isotopically enriched quartz that provides enhanced clutter rejection and improved range and Doppler capabilities. The monopulse radar 50 also comprises a transmitter 51, a receiver 53, a phase measuring device 55, mixers 56 (also referred to as frequency translators), a signal summing junction 57 and antenna 58, having quadrants 59. The low phase noise reference oscillator 52 preferably may use one of the circuits shown in FIG. 4 employing an isotopically enriched quartz resonator 14 as shown in FIG. 5.

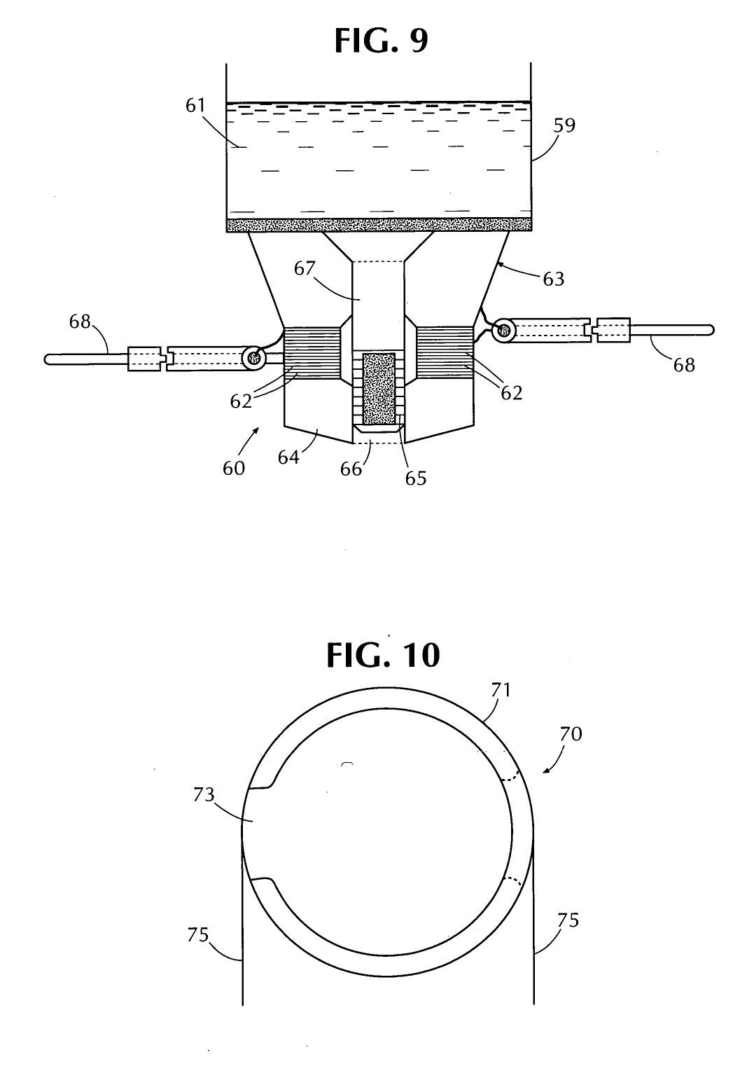

FIG. 9 illustrates an ultrasonic cleaning application of an isotopically enriched piezoelectric device 60 according to the present invention. Referring to FIG. 9, a tank 59 normally containing cleaning solution 61 has an isotopically enriched piezoelectric transducer 60 disposed adjacent to the bottom of the tank 59 to ultrasonically agitate the solution 61. The transducer 60 comprises hollow centered disks 62 of an isotopically enriched piezoelectric material, such as isotopically enriched quartz, disposed between an aluminum body member 63 and a steel cap member 64. Screw 65 holds the transducer assembly together and seals the hollow, central opening 66 which holds a coupling medium 67, typically a gel. Power lines 68 supply electricity to the transducer 62 from a power source (not shown). Prior art transducers of this type typically employed disks 62 made from PZT. The disks 62 made from isotopically enriched quartz according to the present invention, however, provide for a longer lasting transducer and more efficient operation at higher frequencies and higher power levels for improved ultrasonic cleaning.

FIG. 10 is a schematic view of a resonator employing an isotopically enriched piezoelectric material in accordance with the present invention for use as a speaker or buzzer. In particular, a single crystal quartz resonator 70, as shown in FIG. 10, may be advantageously employed in piezoelectric sound components such as speakers (including ultrasonic speakers) , buzzers and transducers. While such devices are usually made from PZT or a piezoelectric plastic film, making such components from an isotopically enriched piezoelectric material, such as isotopically enriched quartz, results in smaller, more efficient, and higher frequency capable components.

Such components made in accordance with the present invention can also be operated at higher power levels without being damaged due the higher thermal conductivity and high resistance to fatigue failure of the isotopically enriched material used. Even the recently introduced non-linear response ultrasonic beam speakers, which convert ultrasonic frequencies to audible frequencies by exploiting a nonlinearity in the atmosphere would be improved by employing isotopically enriched quartz transducers. As shown in FIG. 10, a preferred embodiment of a quartz crystal resonator 70 of the present invention for use as a speaker or buzzer comprises a disk 71 made from a single crystal of isotopically enriched quartz containing at least 99.9% Si28 and 99.9% 016. Large circular electrodes 73, preferably comprising gold or aluminum, are deposited on both sides of the disk 71. Electrical wires 75 connect the resonator 70 to a power supply (not shown).

While the preferred applications of the invention described the above employ isotopically enriched silicon dioxide in the manufacture of quartz crystals for use in piezoelectric devices, the same enrichment of isotopic elements used in other piezoelectric applications (such as zinc oxide, rutile (titanium dioxide), lithium niobate, lithium tantalate, langasite, langatate, and leadzirconate-titanate), will result in similar improvements of the function of those piezoelectric materials and the piezoelectric applications thereof.

Although the invention has been described in terms of particular embodiments in an application, one of ordinary skill in the art, in light of the teachings herein, can generate additional embodiments and modifications without departing from the spirit of, or exceeding the scope of, the claimed invention. Accordingly, it is understood that the drawings and the descriptions herein are proffered by way of example only to facilitate comprehension of the invention and should not be construed to limit the scope thereof.

What is claimed is:

1. A device comprising an isotopically enriched piezoelectric material.

2. The device of claim 1 wherein said isotopically enriched piezoelectric material comprises a single crystal structure.

3. The device of claim 1 wherein said isotopically enriched piezoelectric material comprises isotopically enriched silicon dioxide.

4. The device of claim 2 wherein said isotopically enriched piezoelectric material comprises isotopically enriched silicon dioxide.

5. The device of claim 1 wherein said isotopically enriched piezoelectric material comprises isotopically enriched silicon dioxide having a higher proportion of the Si28 isotope than is present in naturally occurring silicon dioxide.

6. The device of claim 1 wherein said isotopically enriched piezoelectric material comprises isotopically enriched silicon dioxide wherein at least 94% of the silicon component of said silicon dioxide is Si28.

7. The device of claim 1 wherein said isotopically enriched piezoelectric material comprises isotopically enriched silicon dioxide wherein at least 99% of the silicon component of said silicon dioxide is Si28.

8. The device of claim 7 wherein said silicon dioxide has a higher proportion of the O16 isotope than is present in naturally occurring silicon dioxide.

9. The device of claim 1 wherein said isotopically enriched piezoelectric material comprises isotopically enriched silicon dioxide having a higher proportion of the Si29 isotope than is present in naturally occurring silicon dioxide.

10. The device of claim 1 wherein said isotopically enriched piezoelectric material comprises isotopically enriched silicon dioxide having a higher proportion of the Si30 isotope than is present in naturally occurring silicon dioxide.

11. The device of claim 1 wherein said isotopically enriched piezoelectric material comprises isotopically enriched silicon dioxide having a higher proportion of the 016 isotope than is present in naturally occurring silicon dioxide.

12. The device of claim 1 wherein said isotopically enriched piezoelectric material comprises isotopically enriched zinc oxide.

13. The device of claim 1 wherein said isotopically enriched piezoelectric material comprises isotopically enriched titanium dioxide.

14. The device of claim 1 wherein said isotopically enriched piezoelectric material comprises isotopically enriched lithium niobate.

15. The device of claim 1 wherein said isotopically enriched piezoelectric material comprises isotopically enriched lithium tantalate.

16. The device of claim 1 wherein said isotopically enriched piezoelectric material comprises isotopically enriched langasite.

17. The device of claim 1 wherein said isotopically enriched piezoelectric material comprises isotopically enriched langatate.

18. The device of claim 1 wherein said isotopically enriched piezoelectric material comprises isotopically enriched lead-zirconate-titanate.

19. The device of claim 1 wherein said device comprises a clock.

20. The device of claim 1 wherein said device comprises an oscillator.

21. The device of claim 1 wherein said device comprises an acoustic wave filter.

22. The device of claim 1 wherein said device comprises a resonator.

23. The device of claim 1 wherein said device comprises a transducer for an ultrasonic surgical instrument.

24. The device of claim 1 wherein said device comprises a transducer.

25. The device of claim 1 wherein said device comprises a speaker.

26. The device of claim 1 wherein said device comprises an ultrasonic speaker.

27. The device of claim 1 wherein said device comprises a buzzer.

28. The device of claim 1 wherein said device comprises a radar system.

29. The device of claim 28 further comprising a low phase noise reference oscillator having a resonator comprising said isotopically enriched piezoelectric material.

30. The device of claim 1 comprising a transducer for a non-linear response ultrasonic beam speaker system.

31. The device of claim 1 comprising a transducer for an ultrasonic cleaning system.

32. A method for producing a single crystal of an isotopically enriched piezoelectric material comprising the steps of:
obtaining said isotopically enriched material in powder form;
converting said isotopically enriched material powder into dendrite crystals by means of a first hydrothermal process; and
producing a single crystal from said dendrite crystals by means of a second hydrothermal process.
